(19) United States
(12) Patent Application Publication
(10) Pub. No.: US 2026/0358760 A1
(43) Pub. Date: Nov. 12, 2026

(54) Trapped Ion Atomic Clock with Improved Performance and Lower SWaP for Space and Commercial Applications

(71) Applicant: California Institute of Technology, Pasadena, CA (US)

(72) Inventors: Eric A. Burt, Sierra Madre, CA (US); Robert L. Tjoelker, Everson, WA (US); Eric Robert Tardiff, Pasadena, CA (US); James A. McKelvy, Pasadena, CA (US); Michael Owe Toennies, Santa Rosa, CA (US); Anatoliy A. Savchenkov, Pasadena, CA (US); Lin Yi, Monterey Park, CA (US); Vladimir S. Iltchenko, La Canada, CA (US); Wei Zhang, Sierra Madre, CA (US); Andrey B. Matsko, Arcadia, CA (US)

(73) Assignee: California Institute of Technology, Pasadena, CA (US)

(21) Appl. No.: 19/675,235

(22) Filed: May 12, 2026

Related U.S. Application Data
(60) Provisional application No. 63/804,346, filed on May 12, 2025.

(51) Int. Cl. G04F 5/14; C23C 16/40; C23C 16/455

(52) U.S. Cl. CPC G04F 5/14; C23C 16/45555; C23C 16/403

(57) ABSTRACT

An ion clock assembly includes an ion vacuum chamber, a light source, an electron source, a photomultiplier tube (PMT), ultraviolet optics, and additional electronics. The ion trap may include a set of trap rod electrodes that radially confine and a set of endcap electrodes that axially confine the ions. At least one endcap electrode is biased introducing a leak that controls the ion trapping volume. The light source may have an interior surface coated with sapphire using atomic layer deposition (ALD) with a thickness that permits transmission of a vacuum ultra-violet (VUV) wavelength range light. The electron source may have an emitter crystal, a heating element, and emitter bias electronics that apply a negative bias. The negative bias is applied over time, has sufficient energy to ionize a gas species to be trapped yet is below an energy that would ionize a buffer gas.

### CROSS-REFERENCE TO RELATED APPLICATIONS

This application claims the benefit under 35 U.S.C. Section 119(e) of the following co-pending and commonly-assigned U.S. provisional patent application(s), which is/are incorporated by reference herein:

Provisional Application Ser. No. 63/804,346, filed on May 12, 2025, with inventor(s) Eric A. Burt, Robert L. Tjoelker, Eric Tardiff, James A. McKelvy, Michael O. Toennies, Anatoliy A. Savchenkov, Lin Yi, Vladimir S. Iltchenko, Wei Zhang, and Andrey B. Matsko, entitled “Trapped Ion Atomic Clock with Improved Performance and Lower SWaP for Space and Commercial Applications,” attorneys'docket number 176.0269USU1.

### STATEMENT REGARDING FEDERALLY SPONSORED RESEARCH AND DEVELOPMENT

This invention was made with government support under Grant No. 80NM0018D0004 awarded by NASA (JPL). The government has certain rights in the invention.

### BACKGROUND OF THE INVENTION

### 1. Field of the Invention

The present invention relates generally to atomic clocks, and in particular, to a method, system, and apparatus of a trapped ion clock with improved performance and lower SWaP for space and commercial applications.

### 2. Description of the Related Art

(Note: This application references a number of different publications as indicated throughout the specification by reference numbers enclosed in brackets, e.g., [x]. A list of these different publications ordered according to these reference numbers can be found below in the section entitled “References.” Each of these publications is incorporated by reference herein.)

The hydrogen maser is the gold standard for commercial atomic clock performance. This technology is mature, has long instrument life, operates continuously and autonomously, and is used in virtually every timing metrology lab in the world. However, hydrogen masers are large, difficult to qualify for space, and have high inherent environmental sensitivities requiring operation in controlled environments. Hydrogen maser level performance is essential for Position, Navigation, and Timing (PNT). Masers form a crucial component of the PNT infrastructure on earth (for example, the NASA Deep Space Network) and NASA is in the process of defining PNT infrastructure for the moon and planets. This infrastructure would necessarily include precise atomic clocks. While clocks on earth can easily be synchronized with official time standards, this will be difficult on the moon and not feasible at the planets. In addition to hydrogen maser performance, these applications will require a high degree of autonomy and low sensitivity to their environments.

The telecom industry has long used commercial cesium beam atomic clocks for time synchronization. These clocks have relatively low Size, Weight, and Power (SWaP), and the ability to fit in a 3-5 U rack mount package. However, their performance is about 2 orders of magnitude degraded from the hydrogen maser. Industry is now looking for alternatives to cesium beam technology with the same or lower SWaP and higher performance.

A low SWaP atomic clock with hydrogen maser level performance able to fit in a 3U rack mount package is required for both space and commercial ground applications. The solution must be able to operate autonomously in the field and in space and have instrument life longer than 10 years. It must also have low sensitivity to environmental perturbations to be able to operate in varied locations without loss of performance.

### SUMMARY OF THE INVENTION

Trapped mercury ion clock technology has been steadily developed over the past 3 decades [1], [2], [3], [4], [5], and [6]. In 2019, JPL (Jet Propulsion Laboratory) launched the first trapped ion atomic clock to operate in space as part of the Deep Space Atomic Clock mission (DSAC) [7]. This clock had state of the art space clock performance and the SWaP was significantly reduced from previous versions to 19 L/19 kg/55 W. A lifetime estimate of 5 years was extrapolated from approximately 3 years of continuous operation. A successful DSAC mission and NASA SCaN funded Technology Maturation Task (TMT) [8] has led to further research and development advances in the technology.

Embodiments of the invention provide a new design of this technology that is poised to meet each of the emerging PNT and commercial requirements and is the only robust, mature technology currently available able do so. These advances reduce the SWaP and increase instrument lifetime (as used herein the new design may be referred to as the TMT design).

### BRIEF DESCRIPTION OF THE DRAWINGS

Referring now to the drawings in which like reference numbers represent corresponding parts throughout:

FIG. 1 shows a system block diagram for a TMT instrument in accordance with one or more embodiments of the invention;

FIG. 2 shows a photo of an instrument (TMT) breadboard clock demonstrating the components in a flat configuration that will fit into a 3 U rack mount package in accordance with one or more embodiments of the invention;

FIGS. 3A-3C illustrate a TMT prototype clock with all major module forms integrated and identified (FIG. 3A), a CAD image (FIG. 3B) of a clock prototype with the components of FIG. 3A and a complete ion atomic clock (FIG. 3C) in accordance with one or more embodiments of the invention;

FIG. 4A shows an exploded view of details of the TMT ion trap, vacuum tube, and inner magnetic shield assembly;

FIG. 4B shows a cross section of the assembled ion trap, vacuum tube and inner magnetic shield assembly in accordance with one or more embodiments of the invention;

FIG. 4C shows details of the TMT ion trap assembly in accordance with one or more embodiments of the invention;

FIG. 5 illustrates a trap electrode braze conceptual diagram in accordance with one or more embodiments of the invention;

FIG. 6 illustrates a conceptual detail on the electron emitter part in accordance with one or more embodiments of the invention;

FIG. 7 illustrates the modeling and emitter placement in accordance with one or more embodiments of the invention;

FIG. 8A illustrates the prior art DSAC 2-trap system;

FIG. 8B illustrates the simpler TMT single trap system of embodiments of the invention;

FIG. 9 illustrates TMT electronics integration in accordance with one or more embodiments of the invention;

FIG. 10 illustrates a relative size comparison between the actual DSAC and an isometric schematic representation of the new TMT design in accordance with one or more embodiments of the invention;

FIG. 11 illustrates a comparison of the DSAC and TMT vacuum tubes showing decreased complexity for the latter in accordance with one or more embodiments of the invention;

FIG. 12A illustrates a ion trapping potential modeling inside the linear ion trap in accordance with one or more embodiments of the invention; ;

FIG. 12B illustrates the details for the two component endcap electrodes in accordance with one or more embodiments of the invention;

FIG. 13 illustrates linear ion trap potential modeling showing the endcap potential varying as a function of radial distance in the case of applying a DC bias on a single electrode endcap compared with different biases applied to two-electrode endcap in accordance with one or more embodiments of the invention;

FIG. 14 illustrates linear ion trap potential modeling comparing the effective 3-D ion trapping volume while using a single endcap electrode with the trapping volume resulting from a two component endcap electrode implementation in accordance with one or more embodiments of the invention; and

FIG. 15 illustrates the logical flow for using one or more of ion clock assembly variations in accordance with one or more embodiments of the invention.

### DETAILED DESCRIPTION OF THE INVENTION

In the following description, reference is made to the accompanying drawings which form a part hereof, and which is shown, by way of illustration, several embodiments of the present invention. It is understood that other embodiments may be utilized and structural changes may be made without departing from the scope of the present invention.

### System Level Description

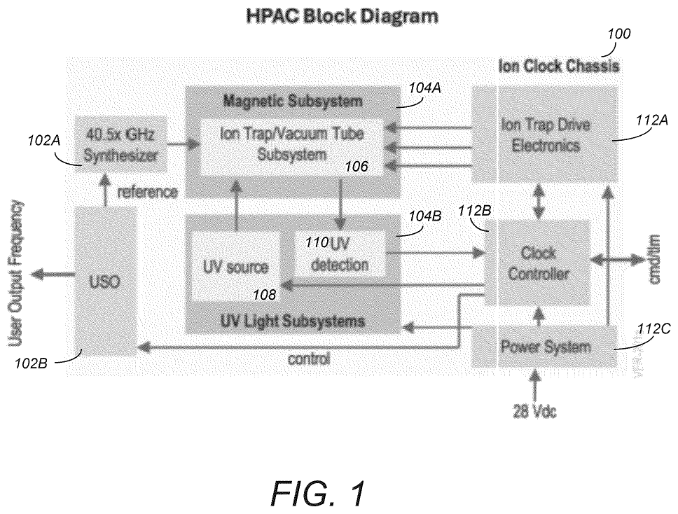

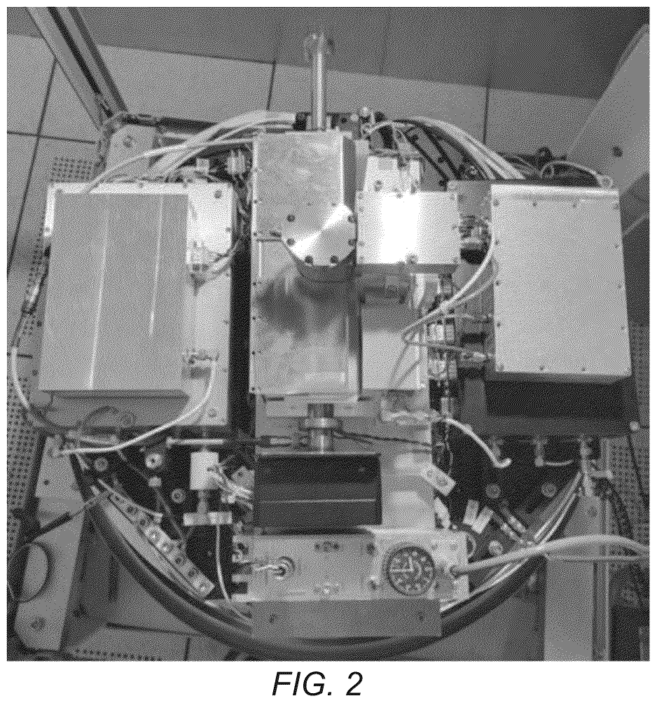

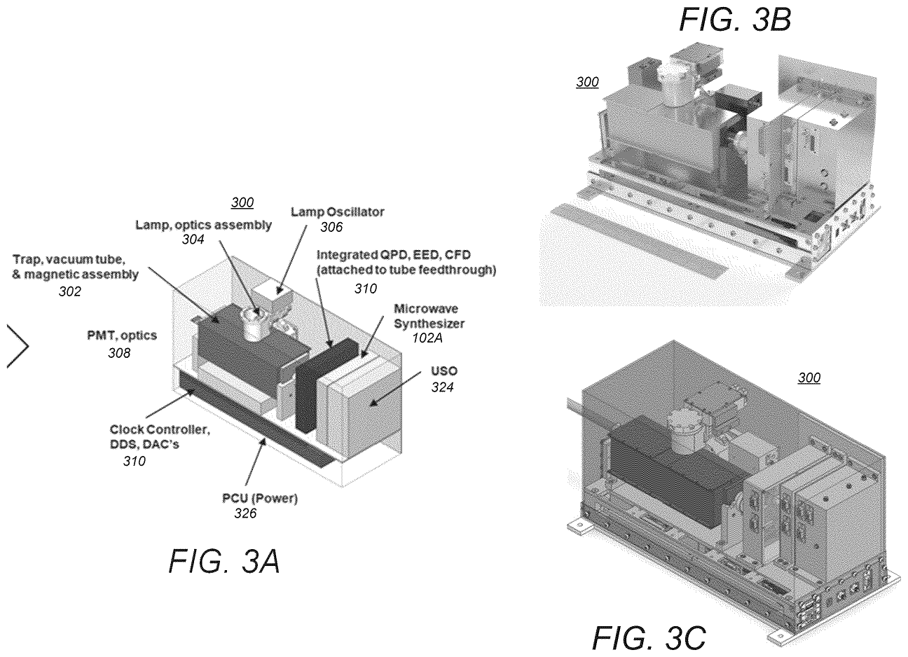

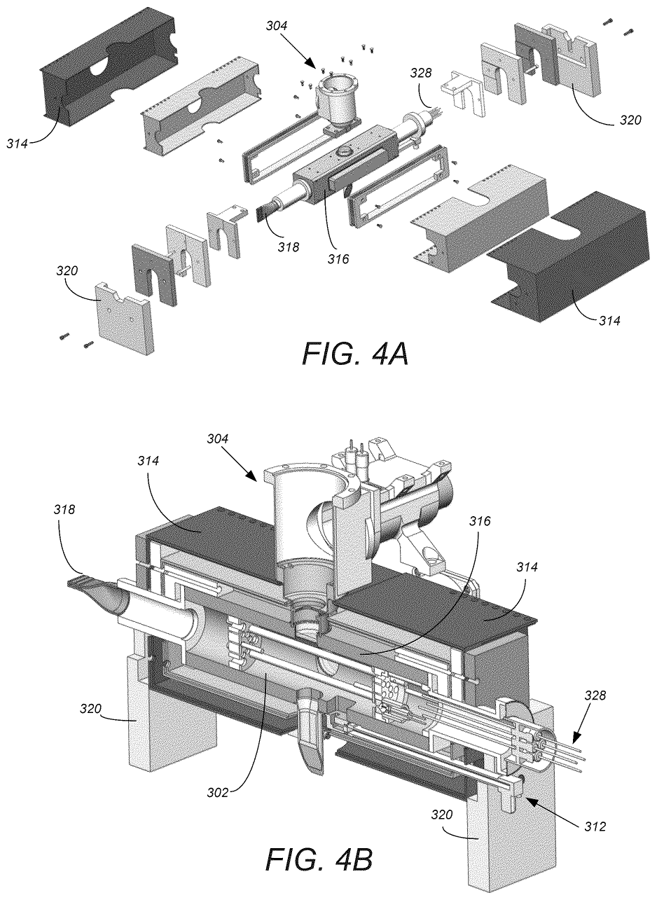

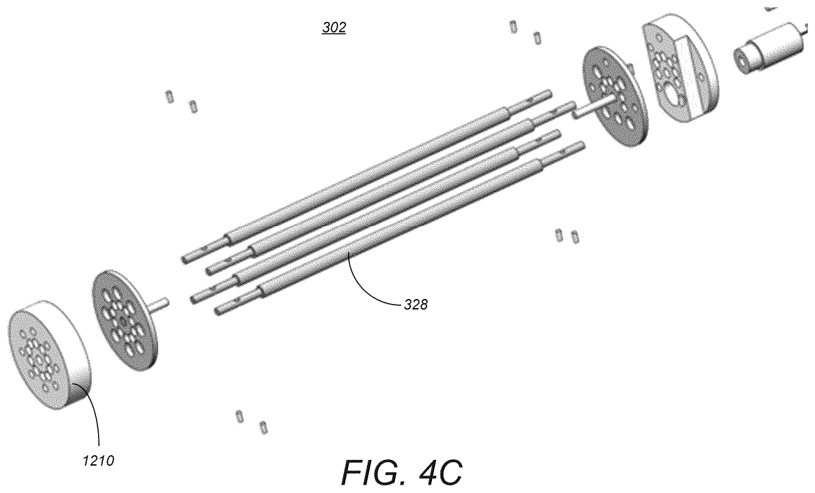

FIG. 1 shows a system block diagram for a TMT instrument in accordance with one or more embodiments of the invention. As illustrated, ion clock block diagram shows an ion clock chassis 100 that contains the frequency synthesis assembly 102 (that includes the synthesizer 102A and USO (ultra-stable oscillator) 102B), the physics package 104 (that includes the magnetic subsystem 104A (including the ion trap/vacuum tube subsystem 106) and the UV light subsystems 104B (including UV source 108 and UV detection 110)), and the key electronics 112 (that includes the ion trap drive electronics 112A, the clock controller 112B, and the power system 112C).
FIG. 2 shows a photo of an instrument (TMT) breadboard clock in a flat configuration whose components will fit into a 3 U rack mount package in accordance with one or more embodiments of the invention. This breadboard instrument already achieves a frequency stability output performance of 3e-13/sqrt(tau) and can operate at 1e-13/sqrt(tau) with its full set of optics.
FIGS. 3A-3C illustrate an integrated TMT prototype clock including a block diagram (FIG. 3A), a CAD image (FIG. 3B) of a clock prototype with the components of FIG. 3A and a complete ion atomic clock (FIG. 3C) (i.e., FIG. 3B enclosed by a third magnetic shield).
FIGS. 4A-4C show details of the TMT ion trap, tube, and shield assembly in accordance with one or more embodiments of the invention. More specifically, FIG. 4A illustrates an exploded view of the vacuum trap tube, magnetic coil and inner magnetic shield assembly; FIG. 4B illustrates the integrated ion trap, tube, and shield assembly cross section; and FIG. 4C illustrates the exploded view of the ion trap assembly (described in further detail below).

The following description references FIGS. 3A-3C and FIGS. 4A-4C. The main assemblies in trapped ion atomic clocks are the ion trap and vacuum chamber 302 (that includes trap electrodes, an ionizer, a vacuum chamber, and a getter pump) (e.g., the trap, vacuum tube, and magnetic assembly), a 194 nm light source 304 (i.e., a lamp and optics assembly), lamp oscillator 306 that drives the lamp 304, a photomultiplier tube (PMT)/optics 308 capable of detecting 194 nm photons, deep UV optics on the input side (located in 304) to guide light into the trap region 302 and output side (not visible) focus the resulting trapped ion fluorescence onto the PMT 308. Electronics to (a) drive the trap 302 (i.e., electronics 112A/310 integrated QPD [quadrupole trap driver] and EED [electron emitter driver] are attached to tube feedthrough, (b) the CFD (C-field driver) drives current in the coils (FIG. 4A) to define the magnetic field environment, and (c) generate the 40.5 GHz clock transition frequency (via component 102A), and (d) the clock controller (112B,310) DDS [direct digital synthesizer], and DAC [digital to analog converter]). Magnetic shields 314 and magnetic coils 316 enclose the clock 300 protecting it from external magnetic perturbations and provide a uniform operating magnetic field. Further, the vacuum tube 302 includes a pump port 318 that is used to prepare and seal an ultra-high vacuum environment for the ion trap, isolated mounts 320 that support the vacuum tube without introducing ground loops, microwave synthesizer 102A that generates 40.5 GHz frequency radiation to drive the ion clock transition in a controlled manner, the USO (ultra stable oscillator) 324 used to provide a reference source for the microwave synthesizer and clock user output, and the power control unit (PCU) 326. Lastly, described in further detail below are the electrical feed through pins 328.

The TMT design includes several key modifications to previous designs: (1) a trapping electrode brazing process; (2) multi-trap system; (3) lower SWaP electronics; (4) streamlined TMT vacuum tube design; and (5) streamlined TMT vacuum tube mount and magnetic coil design. Each of these modifications will be described followed by a further description of novelty and features.

### Trapping Electrode Brazing Process

The trapping electrodes are brazed into their respective ceramic supports using a commercial braze process resulting in a monolithic trap assembly that can be simply inserted into the vacuum chamber for ease of manufacturability. A brazed trap assembly is also hardened for applications susceptible to vibration. Previously it was thought that the braze filler could not include nickel thus dictating a custom braze process that has low yield. It has since been determined that this is an over-constraint and that in small quantities, nickel can be allowed thereby making it possible to use a standard braze process, simplifying fabrication and improving yield.

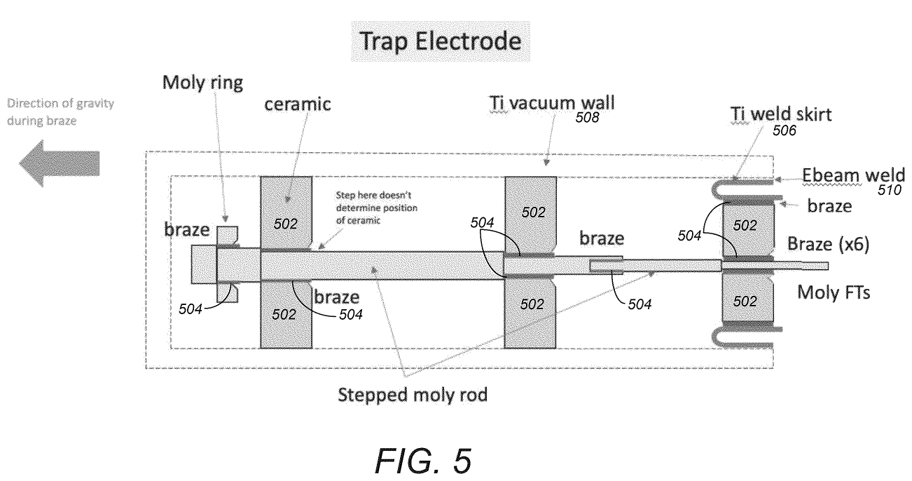

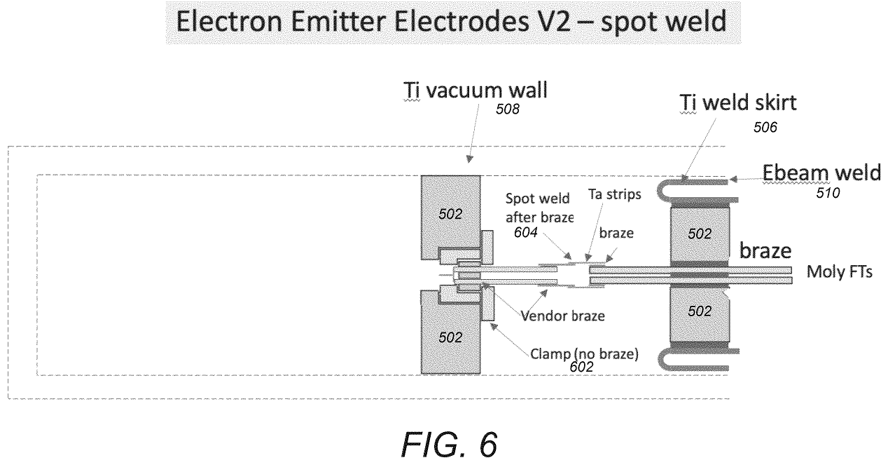

FIG. 5 illustrates a trap electrode braze conceptual diagram in accordance with one or more embodiments of the invention. Ceramics 502 and braze joints 504 are illustrated (note: FIG. 5 is simplified to show only one trap electrode together with all braze joints 504 needed and their approximate geometry.) A titanium weld skirt 506 is brazed to the right most ceramic. All trap electrodes are brazed together with their supporting ceramics 502 providing a monolithic trap assembly and all braze joints 504 are performed using a commercial process. The trap 500 is then inserted into the surrounding vacuum tube (i.e., having a titanium vacuum wall 508) and sealed with an electron-beam weld 510. (Note: furthermore with this design (FIG. 6), if needed, the monolithic trap assembly could be removed with a simple, single machining cut.)

FIG. 6 illustrates a conceptual detail on the electron emitter part in accordance with one or more embodiments of the invention. It cannot be installed in the trap assembly during the braze process because it has already been brazed during its own fabrication. Instead, it is installed after the braze, secured with a clamp 602, and spot welded 604 to feedthroughs in the ceramic 502.

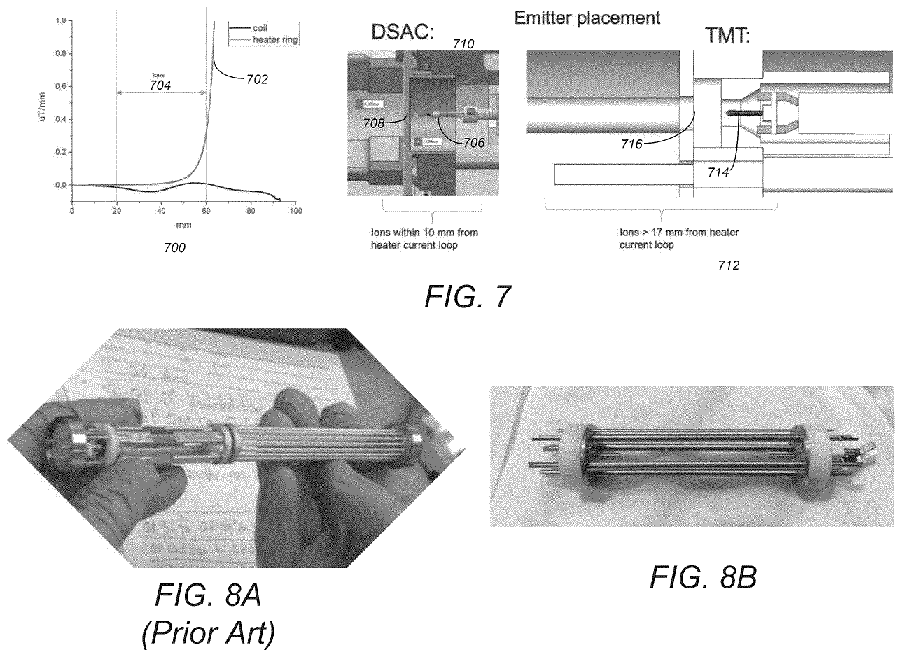

In addition, electro-magnetic field modeling may be used to determine the optimal position of the electron emitter so that its magnetic field is sufficiently reduced at the location of the trapped ions. FIG. 7 illustrates the modeling and emitter placement in accordance with one or more embodiments of the invention. Trace 702 in the graph 700 on the left shows the modeled magnitude of the magnetic field created by the electron emitter superimposed with the region occupied by the trapped ions 704. The sharp increase in the magnetic field and associated field gradient are caused by the very close proximity of the electron emitter 706 to the trapped ions 708 shown in the middle image 710 of the DSAC approach. The image 712 on the right shows the geometry of the TMT approach, which places the emitter 714 7 mm further way (from the trapped ions 716), and thus moving the region occupied by the ions relative to the emitter field 7 mm to the left in the graph 700, thereby greatly reducing the magnetic field that the trapped ions would experience.

### Single Quadrupole-only Trap Approach

DSAC implemented a two-trap system consisting of a quadrupole trap and a multipole trap to provide long-term clock stability. It has since been demonstrated that a quadrupole only trap alone can achieve long-term stability far better than any currently operating space or commercial ground clock. The TMT design is based on a single quadrupole-only trap approach, thereby reducing both SWaP and complexity.

FIG. 8A illustrates the prior art DSAC 2-trap system [6] and FIG. 8B illustrates the simpler TMT single trap system [8] of embodiments of the invention.

### Lower Swap Electronics

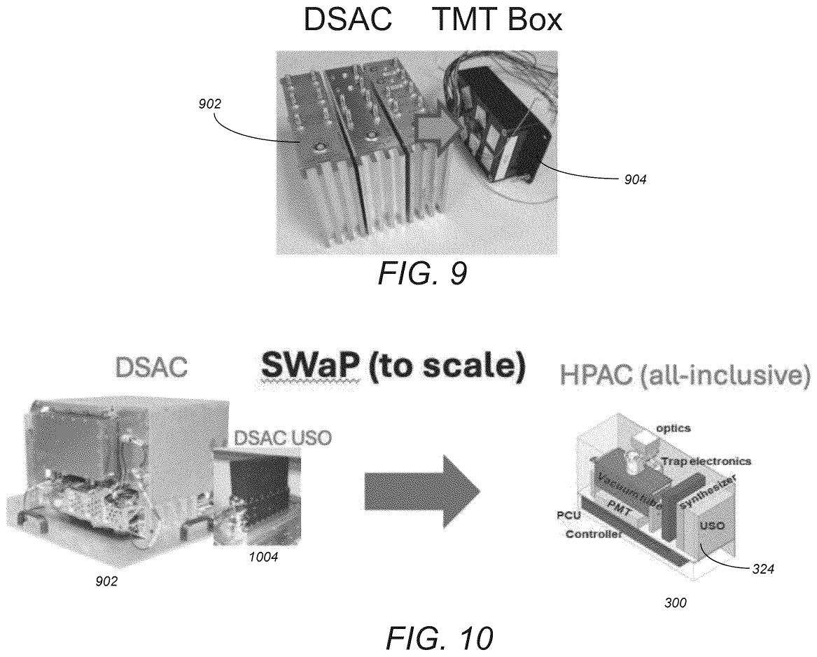

Research and development during the TMT project demonstrated that much lower SWaP electronics could be built without degrading clock performance. The reduced SWaP is achieved by removing excess space, using multiple board layers and reduced component size, and integrating electronics boxes where possible. FIG. 9 illustrates one component of TMT electronics integration in accordance with one or more embodiments of the invention. DSAC-era electronics 902 (112A) are shown on the left and a TMT box implementation 904 (310) that performs the same function is shown on the right. One of the DSAC electronics boxes is eliminated and the two remaining boxes are integrated into one box by using multi-layer electronics boards. The TMT box is attached directly to the vacuum tube electrical feedthroughs, thereby eliminating many cables and reducing space.

All boards in the TMT design 300 have a footprint of less than 15 cm×10 cm. The estimated SWaP of the overall TMT instrument design 300 is 10 L/10 kg/33 W, down from the 19 L/19 kg/55 W achieved in the DSAC instrument 902.

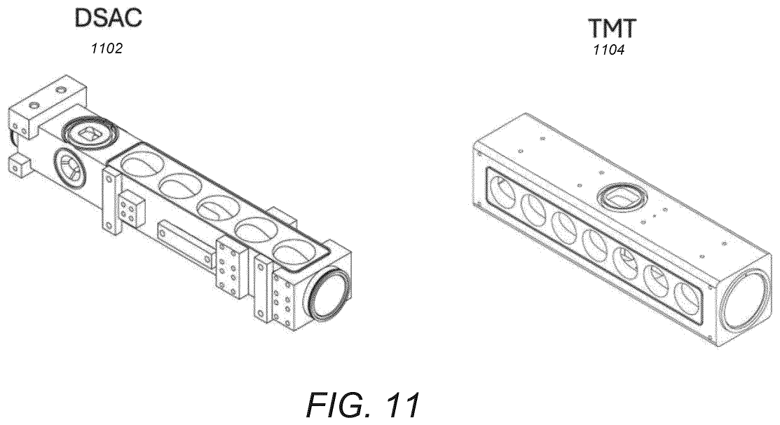

FIG. 10 illustrates a size comparison between the actual DSAC 902 and a schematic of the new TMT design 300 (the details of which are shown in FIG. 3A). More specifically, FIG. 10 illustrates a scale comparison of size between the actual DSAC build 902 and a schematic 300 of the TMT design. Note that the DSAC local oscillator (USO) 1004 was separate from the main instrument (in the DSAC design 902) and is illustrated as an additional component 1004. In contrast, in the TMT design, the USO 324 is integrated into the TMT instrument 300.

### Streamlined TMT Vacuum Tube Design

The TMT vacuum tube design is streamlined for ease of manufacturability by removing unnecessary structure that makes the tube more difficult to fabricate. FIG. 11 illustrates a comparison of the DSAC 1102 and TMT vacuum tubes 1104 showing decreased complexity for the latter. As illustrated, there are fewer bosses and cuts, while maintaining functionality, making this primary component of the technology easier to manufacture.

Streamlined TMT Vacuum Tube Mount and Magnetic Coil Design

Further to the above, the TMT vacuum tube mount and magnetic coil design may be streamlined for ease of manufacturability and made modular to greatly simplify assembly around the vacuum tube (FIGS. 4A,4B).

### Features, Novelty and Advantages

Embodiments of the invention differ from all other space and commercial clocks in that it uses an electromagnetic trap to confine ions, thereby shutting off interactions with the surrounding vacuum chamber walls and associated uncontrolled variations in the clock frequency. This sets the trapped ion technology apart from other current technologies because it is much less sensitive to potential frequency drift and therefore is uniquely suited to applications requiring autonomy.

The novelty of the TMT design from prior art trapped ion clock designs includes: (1) smaller size while maintaining high performance, largely achieved by better integrated multi-layer electronics and integrating a smaller steerable high performance Local Oscillator (LO); and (2) easier manufacturability achieved by using a standard braze process in place of a custom braze process and by simplifying the design of the vacuum tube, vacuum tube mount, and magnetic assembly. In this regard, the TMT ion clock of embodiments of the invention is the first clock to use a new sapphire-based UV light source developed for enhanced life.

Referring again to FIG. 1, the compact ion clock assembly is provided that includes an ion trap vacuum enclosure and RF ion trap 106, electron emitter (included in 112A), magnetic field coils (within magnetic subsystem 104A), electronic drivers 112A, optical/UV source 108, optical/UV detector 110, local oscillator 102B, and microwave synthesizer 102A. Further, the ion clock of FIG. 1 may be packaged in an optimized system configuration as illustrated in FIGS. 3A-3C, 4A-4C and, as the TMT design 300 in FIG. 10.

Further to the above, SWaP may be optimally reduced while not sacrificing performance by: (1) eliminating one of the two traps used in previous designs as shown in FIGS. 8A-8B; (2) eliminating the electronic driver associated with the removed trap; (3) integrating electronics into the same box where possible without incurring extra cross talk as shown in FIG. 9; (4) employing multi-layer electronics boards; (5) using lower power electronics components where possible without sacrificing performance; (6) optimizing trap geometry to maximize the number of trapped ions and minimizing their interaction with stray electromagnetic fields; and (7) eliminating empty space where possible.

In addition, the coil form design may be changed to be a simple rectangle that can be wound and snapped on to the vacuum enclosure in minutes (the current DSAC custom geometry requires days).

In one or more embodiments, the ion trap enclosure may also be maximally separated from the electronics modules and local oscillator to reduce the unwanted cross-talk among the components.

### Ion Trap End-Cap Electrode for Ion Number Control

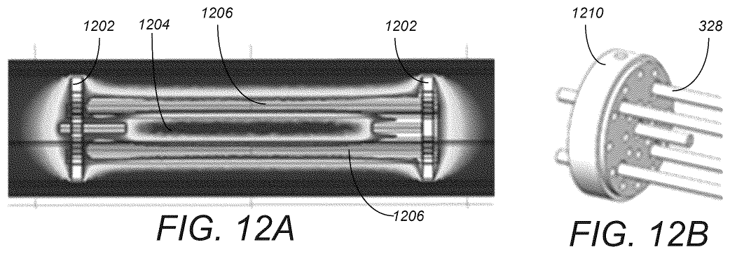

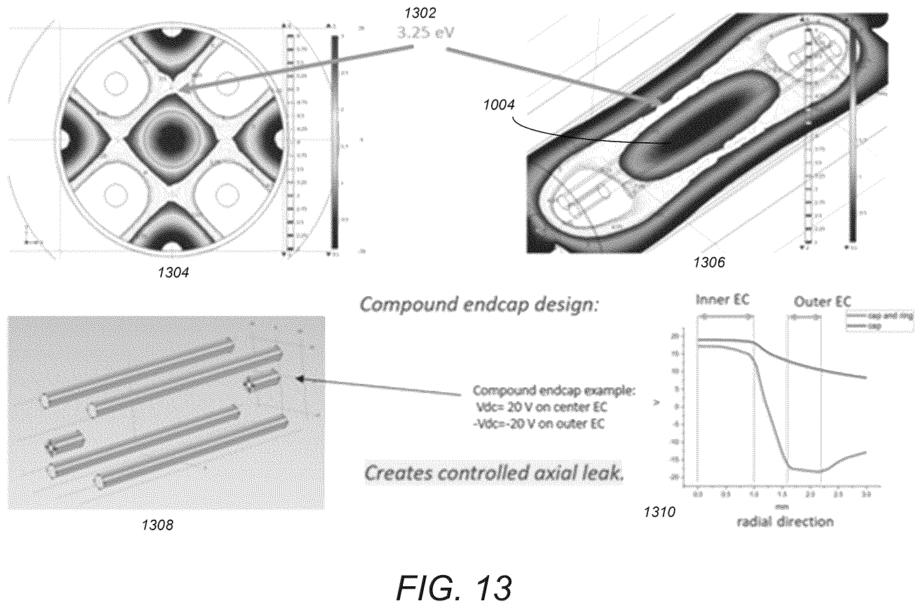

In linear ion trap based atomic clocks, an RF potential is applied to a series of trap rod electrodes to confine ions in two (2) dimensions. Ions are confined in the third dimension with simple DC biased electrodes 1202 located at each end of the trap rods (see FIG. 12A). These are commonly referred to as “endcaps” 1202. In this regard, FIG. 12A illustrates a linear ion trap showing the trap volume 1204 resulting from RF biased trap rods 1206 and DC biased endcaps 1202. In this development, embodiments of the invention have implemented a two-component endcap electrode (e.g. FIG. 12B) that can be individually biased to shape the resulting trapping potential. More specifically, FIG. 12B illustrates the details for the two component endcap electrodes 1202. In this example, the endcap 1202 consists of a central pin 328 (biased positive) and a disk 1210 (biased negative) (an exploded/detailed view of the end-cap is illustrated in FIG. 4C). FIG. 13 illustrates linear ion trap potential modeling showing the endcap potential varying as a function of different DC bias on a single and two-electrode endcap. With the mechanism described herein, a small, controllable leak 1302 can be created in the ion trap (with the radial leak 1302 shown on a radial section in the left image 1304 and on an axial section in the right image 1306. This can be used to provide a passive or active means of improved ion number control, an important parameter resulting in increased clock stability.

The time averaged trap potential created by the linear ion trap electrode structure creates an effective trapping volume 1204 (see FIG. 12A and FIG. 13). The maximum ion number that the trap can hold is proportional to this volume. A larger trapped ion number provides the benefit of increased clock signal to noise ratio (SNR), which results in improved clock output stability. Furthermore, in clock operation, it is ideal that the number of trapped ions remains constant over time as changes in ion number can result in a second order Doppler shift of the clock frequency output (a relativistic effect). This shift is often the leading systematic effect in room temperature trapped ion atomic frequency standards.

When ions are confined, mutual Coulomb repulsion (space charge) pushes ions radially off the central trap node of the linear ion trap where they will experience the RF trapping field. The trap volume will fill until the equilibrium ion energy (temperature) is equivalent to the trap well depth. At this point any additional ions will be lost from the trap. In most linear ion trap implementations, the trap is loaded to this equilibrium point. At this point, the instantaneous ion load rate and ion loss rate are in equilibrium. While many parameters over time or varying operating environments may continue to impact these rates, the predominant loss mechanism is typically ions falling out of a maximally filled trap volume. As seen in FIG. 13, ions may then spill out/leak 1302 along the entire perimeter of the potential well. In this regard, the lower left image 1308 illustrates the modeled trap electrode configuration (in this case, the modeled two-electrode endcap consists of an inner and outer cylinder). Further, the graph 1310 shows the trap potential in volts (vertical axis) with respect to the radial distance in mm (horizontal axis). Also shown is the location of the inner (or central) endcap (EC) and outer endcap(EC).

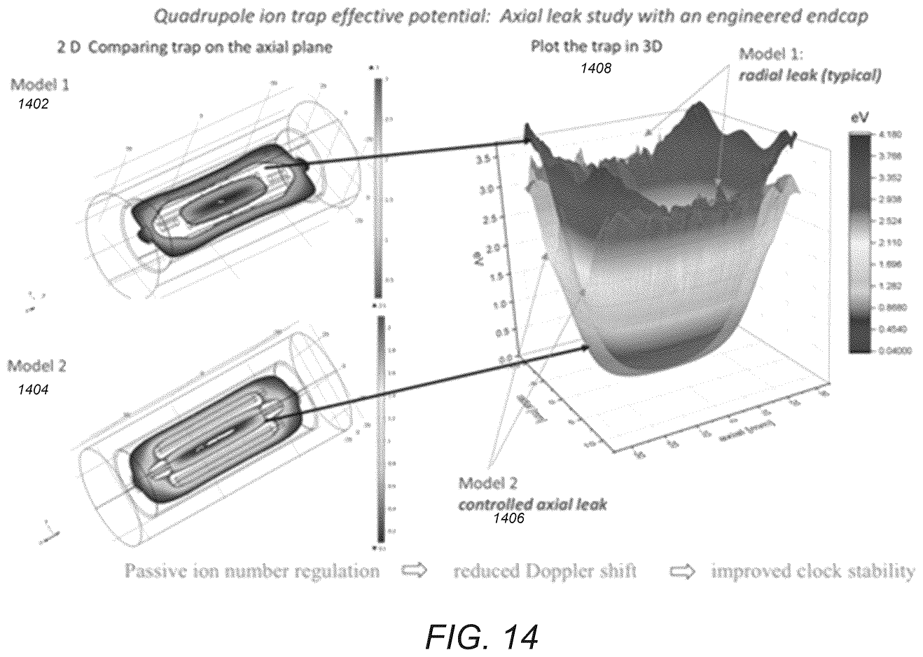

In embodiments of the invention, a two-electrode endcap (see FIG. 12B) can be biased to introduce a very small leak 1406 over only a small portion of trap potential rim (see FIG. 13 and FIG. 14). Furthermore, this fine “leak” can be tuned with simple DC control on one of the two endcap electrode components. With a controllable leak this provides a control point that can servo the ion loss rate to match the ion load rate (which may change over time or operating environment changes). When appropriately implemented, this mechanism may result in a more stable trapped ion number. In practice, this then translates to a more stable second order Dopler shift, and therefore a more stable atomic clock (see FIG. 14).

More specifically, FIG. 14 illustrates linear ion trap potential modeling comparing the effective 3-D ion trapping volume while using a single endcap electrode (model 1 1402) compared to the trapping volume resulting from the two component endcap electrode (model 2 1404). An example of a controllable small axial leak 1406 is shown via the 3D plot 1408 of the trap potential.

In view of the above, embodiments of the invention provide an ion trap consisting of four molybdenum rods and end-caps attached to ceramic supports. Such end-caps may consist of a disk 1210 and a central pin 328 isolated from each other, which creates a controlled leak in the ion trap enabling precise ion number control. Further, the trapping rods may be brazed into their respective ceramic supports using a standard (non-custom) commercial braze process resulting in a monolithic trap assembly that can be simply and reliably fabricated and rigid to vibration.

### Electron Emitter Optimized Location

In one or more embodiments, the electron emitter may have a location optimized to be at the distance approximately equal to the distance between the rods in the quadrupole trap to avoid a magnetic gradient in the trapping region as shown in FIG. 7.

### Electron Emitter Extended Life

In trapped mercury ion atomic clocks, an electron emitter is used to generate a beam of high energy electrons used, often in pulsed mode, to ionized neutral mercury into mercury ions. The beam is created by first heating the emitter crystal to high temperature (1100 Kelvin) and then applying a negative bias of about −140 V to it relative to a surrounding grid structure. The heat is enough to free electrons from the emitter crystal, and the bias voltage directs them into a beam. During normal operation electron emitters will age primarily due to evaporation at the high operating temperature, and bombardment of ambient buffer gas ions also created by the electron beam. These processes result in a lifetime of approximately five (5) years.

Embodiments of the invention have determined that the emitter will still function normally at a much lower bias voltage than previously thought possible. At a bias of −18 V, electrons still have enough energy to ionize mercury, while much less able to ionize the helium buffer gas in the clock. This conservative operational mode called “trickle mode” loading, albeit slower than the normal mode of operation, results in a lower helium ion bombardment rate, which can slow the emitter aging process thereby enabling 10-year life or greater in the emitter and for the clock.

Accordingly, enabled by the extreme high vacuum achieved, the electron emitter of embodiments of the invention may be operated using a new low power method that extends electron emitter life and reduces buffer gas depletion.

### ALD Coating

Currently a plasma discharge light source or lamp is used by the prior art trapped ion atomic clock technology. These lamps consist of a small hermetically sealed fused silica envelope backfilled with mercury and an argon buffer gas. They currently have a lifetime of several years and limit the overall lifetime of the clock. The life-limiting mechanism is most likely due to high energy mercury plasma ions colliding with the fused silica walls, dislodging oxygen (fused silica is SiO₂), and forming mercury oxide, which is then trapped in the fused silica substrate. After several years, the backfilled mercury inside the lamp is depleted in this way and it is no longer possible to sustain a mercury plasma discharge.

It has long been known in the UV lamp industry that sapphire is much less vulnerable to this process while still remaining transmissive in the deep UV, however the best method for doing so has remained elusive since sapphire is much harder to work with than fused silica. Embodiments of the invention have devised a procedure for introducing sapphire into the interior of a fused silica envelope using Atomic Layer Deposition (ALD). Of all the ways that sapphire lamps were manufactured, ALD coating on the inner surface had the best properties. In particular, it can withstand temperatures up to 800 C, which is needed for the high-temperature vacuum bakeout that is used to prepare the lamps and subsequent high-temperature pinch-off from the parent manifold. In addition, ALD sapphire coatings can be laid down with a precise thickness thereby enabling a thickness choice that can be anti-reflective at 194 nm. ALD sapphire coated lamps have the potential for 10-year life or longer, thereby enabling longer-lived trapped mercury ion clocks.

Accordingly, in one or more embodiments, the optical source of an ion clock assembly consists of an ALD sapphire coated fused silica mercury lamp to increase lamp life and overall system life and to improve the detected signal-to-noise ratio.

### Miniature Photo-Multiplier Tube

In one or more embodiments of the invention, the optical detector of the ion clock is represented by a miniature photo-multiplier tube and a slit optimized to match the ion cloud image of the ions confined in the ion trap.

### Vacuum Getter Pump

In one or more embodiments of the invention, the ion trap vacuum enclosure of the ion clock further includes a vacuum getter pump.

### Ion Clock Embodiments and Summary

In view of the above, the ion clock assemblies of embodiments of the invention have an ion trap vacuum chamber, a light source that emits photons, an electron source, a photomultiplier tube (PMT) capable of detecting photons, ultraviolet optics that guide the photons into the ion trap and focus resulting trapped ion fluorescence onto the PMT, and additional electronics that: (i) drive the ion trap; (ii) define a magnetic field environment; and (iii) generate a clock transition frequency and magnetic shields to enclose the ion atomic clock protecting it from external magnetic perturbations.

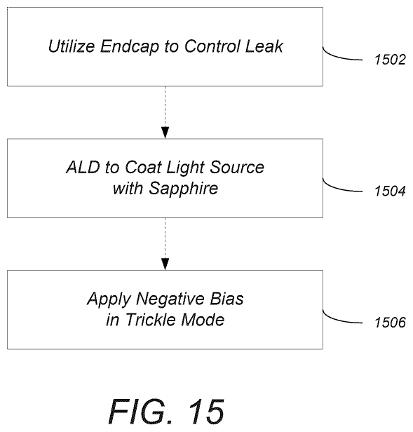

Various modifications to/different constructions of one or more of these components provide for a more stable or extended life atomic clock. FIG. 15 illustrates the logical flow for using one or more of ion clock assembly variations in accordance with one or more embodiments of the invention. In FIG. 15, the dashed lines between each step indicate that each step is optional and independent of the other.

### Ion Trap Endcap

At step 1502, in one variation, the ion trap endcap electrodes in the vacuum chamber is modified/constructed differently. Specifically, a set of trap rod electrodes radially confine ions, and a set of endcap electrodes axially confine the ions. In such embodiments, at least one of the endcap electrodes is modified and biased such that a leak is introduced that allows control of an ion trapping volume and resulting trapped ion number.

In additional embodiments, at least one of the endcap electrodes is broken into two or more components including a pin having a first bias and a disk that having a second different bias. The first bias and the second different bias form the leak. Further, the leak is controlled by adjusting a difference between the first bias and the second different bias. In this regard, the leak is tuned using a DC control on one of the two or more components (i.e., the pin or disk). The leak provides a control point that servos an ion loss rate to match an ion load rate. Further, the controllable leak results in a more stable second order Dopler shift and a more stable ion clock assembly compared to ion clock assemblies that do not have the controllable leak.

### ALD Saphire Coating

At step 1504, another different construction/modification of one or more embodiments of the invention is to the light source. Specifically, an interior surface of a light source lamp is coated with sapphire using atomic layer deposition (ALD). The interior surface confines an RF discharged plasma, and the sapphire coating provides protection of the light source lamp from the RF discharged plasma. Further, the sapphire coating has a thickness that permits transmission of a wavelength in a vacuum ultra-violet (VUV) range. As used herein, deep UV (DUV) is in the 200-300 nm range and VUV is 100-200 nm range (e.g., 194 nm). Thus, the chosen thickness is anti-reflective at ~194 nm.

The sapphire coating inside a fused silica envelope provides protection of the interior surface of the light source from penetration and loss of mercury atoms by in-diffusion into fused quartz walls and resulting depletion of mercury content and deterioration of useful VUV light output. The ALD process enables the sapphire coating to be laid down with a defined thickness enabling a thickness choice. In addition, the light source with sapphire coating extends the life of the light source compared to light sources without the ALD sapphire coating.

### Trickle Mode

At step 1506, one or more embodiments of the invention provide for a different/modified electron source operation to create what is described to above as a “trickle mode”. In such embodiments, the electron source has an emitter crystal, a heating element that heats the emitter crystal to free electrons, and emitter bias electronics that apply a negative bias (e.g., −18V) relative to a surrounding grid structure that directs the freed electrons into a beam. The negative bias is continuously applied over time in a trickle mode. Further, the negative bias has sufficient energy to ionize a gas species to be trapped (e.g., mercury), yet the sufficient energy is below an energy that would ionize a buffer gas (e.g., helium). Further, the trickle mode extends a life of the ion clock assembly compared to ion clock assemblies that do not use the trickle mode (e.g., compared to clock assemblies that use negative biases of about −140V).

### Conclusion

This concludes the description of the preferred embodiment of the invention. Further to the above, embodiments of the invention may be utilized in ground clocks or space clocks in Earth orbit, the moon to mars, and deep space missions. This particular atomic clock is of current interest to enable Earth-independent local Position, Navigation, and Timing (PNT) at the moon and Mars.

The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

### REFERENCES

[1] R. L. Tjoelker, C. Bricker, W. Diener, R. L. Hamell, A. Kirk, P. Kuhnle, L. Maleki, J. D. Prestage, D. Santiago, D. Seidel, D. A. Stowers, R. L. Sydnor, T. Tucker, “A Mercury Ion Frequency Standard Engineering Prototype for the NASA Deep Space Network”; Proc. of the 50th Annual Symp. on Frequency Control, Honolulu, Hawaii Jun. 5-7, 1996.
[2] J. D. Prestage, R. L. Tjoelker, and L. Maleki, “Higher Pole Linear Traps for Atomic Clock Applications,” Proceedings of the 1999 Joint Meeting EFTF-IEEE IFCS. See also NTR's 45380 and 44271.
[3] R. L. Tjoelker, J. D. Prestage, P. A. Koppang, T. B. Swanson, “Stability Measurements of a JPL Multi-pole Mercury Trapped Ion Frequency Standard at the USNO”; Proc. of the 2003 Joint Meeting of the 17th EFTF and 58^{th} Ann. Symp. On Frequency Control, Tampa, FL; May 5-8, 2003.
[4] E. A. Burt, R. L. Tjoelker, “A Compensated Multi-pole Linear Ion Trap Mercury Frequency Standard for Ultra-Stable Timekeeping,” IEEE Trans UFFC 55, 2586 (2008).
[5] R. L Tjoelker, E. A. Burt, S. Chung, R. L. Hamell, J. D. Prestage, B. Tucker, P. Cash, R. Lutwak. “Mercury atomic frequency standards for space-based navigation and Timekeeping.” In Proc. 43rd annual Precise Time and Time Interval (PTTI) Systems and Applications Meeting, 209-304 (Institute of Navigation, 2011).
[6] Robert L. Tjoelker, John D. Prestage, Eric A. Burt, Pin Chen, Yong J. Chong, Sang K. Chung, William Diener, Todd Ely, Daphna G. Enzer, Hadi Mojaradi, Clay Okino, Mike Pauken, David Robison, Bradford L. Swenson, Blake Tucker, and Rabi Wang. “Deep Space Atomic Clock (DSAC) for a NASA Technology Demonstration Mission.” IEEE Trans. Ultrason. Ferroelectr. Freq. Control 63, 1034-1043 (2016).
[7] Burt, E. A., J. D. Prestage, R. L. Tjoelker, D. G. Enzer, D. Kuang, D. W. Murphy, D. E. Robison, J. M. Seubert, R. T. Wang, and T. A. Ely. “Demonstration of a Trapped-Ion Atomic Clock in Space.” Nature 595, no. 7865 (July 2021): 43-47. https://doi.org/10.1038/s41586-021-03571-7.
[8] Burt, E. A., T. A. Ely, and R. L. Tjoelker. “DSAC and next Generation High Stability, Long Life Trapped Mercury Ion Frequency Standards.” Journal of Physics: Conference Series 2889, no. 1 (November 2024): 012014. https://doi.org/10.1088/1742-6596/2889/1/012014.

What is claimed is:

1. An ion clock assembly, comprising:
(a) an ion trap vacuum chamber;
(b) a light source that emits photons;
(c) an electron source comprising:
(i) an emitter crystal;
(ii) a heating element that heats the emitter crystal to free electrons;
(iii) emitter bias electronics that apply a negative bias relative to a surrounding grid structure that directs the freed electrons into a beam, wherein:
(1) the negative bias is applied in a trickle mode;
(2) the trickle mode continuously applies the negative bias over time;
(3) the negative bias has sufficient energy to ionize a gas species to be trapped; and
(4) the sufficient energy is below an energy that would ionize a background buffer gas;
(d) a photomultiplier tube (PMT) capable of detecting photons;
(e) ultraviolet optics that guide the photons into the ion trap and focus resulting trapped ion fluorescence onto the PMT; and
(f) additional electronics that:
(i) drive the ion trap;
(ii) define a magnetic field environment; and
(iii) generate a clock transition frequency and magnetic shields to enclose the ion atomic clock protecting it from external magnetic perturbations.

2. The ion clock assembly of claim 1, wherein:
the negative bias is −18V.

3. The ion clock assembly of claim 1, wherein:
the gas species to be trapped is 199 Hg+; and
the background buffer gas is helium.

4. The ion clock assembly of claim 1, wherein:
the trickle mode extends a life of the ion clock assembly compared to ion clock assemblies that do not use the trickle mode.

5. An ion clock assembly, comprising:
(a) an ion trap vacuum chamber;
(b) a light source that emits photons, wherein:
(i) an interior surface of a light source lamp is coated with sapphire using atomic layer deposition (ALD);
(ii) the interior surface confines an RF discharged plasma;
(iii) the sapphire coating provides protection of the light source lamp from the RF discharged plasma; and
(iv) the sapphire coating has a thickness that permits transmission of a wavelength in a vacuum ultra-violet (VUV) range;
(c) an electron source;
(d) a photomultiplier tube (PMT) capable of detecting photons;
(e) ultraviolet optics that guide the photons into the ion trap and focus resulting trapped ion fluorescence onto the PMT; and
(f) additional electronics that:
(i) drive the ion trap;
(ii) define a magnetic field environment; and
(iii) generate a clock transition frequency and magnetic shields to enclose the ion atomic clock protecting it from external magnetic perturbations.

6. The ion clock assembly of claim 5, wherein:
the sapphire coating provides protection of the interior surface of the light source from penetration and loss of mercury atoms by in-diffusion into fused quartz walls and resulting depletion of mercury content and deterioration of useful VUV light output.

7. The ion clock assembly of claim 5, wherein:
the interior of the surface of the light source lamp comprises a fused silica envelope.

8. The ion clock assembly of claim 5, wherein:
the ALD enables the sapphire coating to be laid down with a defined thickness enabling a thickness choice.

9. The ion clock assembly of claim 5, wherein:
the thickness is anti-reflective at 194 nm.

10. The ion clock assembly of claim 5, wherein:
the light source with sapphire coating extends a life of the light source compared to light sources without the sapphire coating.

11. An ion clock assembly, comprising:
(a) an ion trap vacuum chamber, comprising:
(i) a set of trap rod electrodes that radially confine ions;
(ii) a set of endcap electrodes that axially confine the ions; and
(iii) at least one of the endcap electrodes is biased such that a leak is introduced that allows control of an ion trapping volume and resulting trapped ion number;
(b) a light source that emits photons;
(c) an electron source;
(d) a photomultiplier tube (PMT) capable of detecting photons;
(e) ultraviolet optics that guide the photons into the ion trap and focus resulting trapped ion fluorescence onto the PMT; and
(f) additional electronics that:
(i) drive the ion trap;
(ii) define a magnetic field environment; and
(iii) generate a clock transition frequency and magnetic shields to enclose the ion atomic clock protecting it from external magnetic perturbations.

12. The ion clock assembly of claim 11, wherein:
at least one of the endcap electrodes is broken into two or more components comprising a pin having a first bias and a disk that having a second different bias;
the first bias and the second different bias form the leak;
the leak is controlled by adjusting a difference between the first bias and the second different bias.

13. The ion clock assembly of claim 12, wherein:
the leak is tuned using a DC control on one of the two or more components.

14. The ion clock assembly of claim 11, wherein:
the leak provides a control point that servos an ion loss rate to match an ion load rate.

15. The ion clock assembly of claim 11, wherein:
the controllable leak results in a more stable second order Doppler shift and a more stable ion clock output compared to ion clock assemblies that do not have the controllable leak.
